(19) United States
(12) Patent Application Publication
(10) Pub. No.: US 2010/0327304 A1
(43) Pub. Date: Dec. 30, 2010

(54) ORGANIC EL DEVICE AND DESIGN METHOD THEREOF

(76) Inventors: Shinichiro Sonoda, Ashigarakami-gun (JP); Toshiro Takabashi, Ashigarakami-gun (JP); Manabu Tobise, Ashigarakami-gun (JP)

Correspondence Address: BIRCH STEWART KOLASCH & BIRCH, PO BOX 747, FALLS CHURCH, VA, 22040-0747, US

(21) Appl. No.: 12/826,106

(22) Filed: Jun. 29, 2010

(30) Foreign Application Priority Data
Jun. 30, 2009 (JP) 2009-156351

(51) Int. Cl. H01L 51/52

(52) U.S. Cl. 257/98; 257/E51.018

(57) ABSTRACT

An organic electroluminescence device including an organic electroluminescence display part which includes an anode, a cathode and at least a light-emitting layer disposed therebetween, and a lens which controls an optical path of light emitted from the light-emitting layer, wherein the organic electroluminescence device has a ratio of A to B (A/B) of greater than 1, where A denotes a light-extraction efficiency in terms of front brightness when the lens is placed on a surface from which the light is extracted, and B denotes a light-extraction efficiency in terms of front brightness when the lens is not placed on the surface from which the light is extracted, and wherein the organic electroluminescence device has a ratio of φ to a (φ/a) of 1.0 or greater, where a denotes the maximum length of a side of the light-emitting layer and φ denotes an effective diameter of the lens.

### BACKGROUND OF THE INVENTION

1. Field of the Invention

The present invention relates to an organic EL device that exhibits high light-extraction efficiency and reduced image bleeding, and to a design method thereof.

2. Description of the Related Art

Organic electroluminescence devices (organic EL devices) are self-emitting-type display devices, and are used in displays and lightings. Organic EL displays have several advantages over conventional CRTs or LCDs in terms of display performances, such as high visibility and no viewing-angle-dependency. Furthermore, organic EL lightings have advantages in that they can be made to be lightweight and thin-layered. In addition, organic EL lightings may open up a possibility of lightings with novel shapes through use of flexible substrates.

Although such organic EL devices possess several excellent characteristics, the refractive indices of the constituent layers thereof, including a light-emitting layer, are generally higher than that of air. For example, the refractive indices of organic thin layers of organic EL devices (e.g., a light-emitting layer) are between 1.6 and 2.1. For this reason, emitted light tends to be totally reflected on the interfaces, and thus, the light-extraction efficiency is less than 20% and most of the emitted light is lost.

For example, an organic EL display part of generally known organic EL devices includes, on a substrate, an organic compound layer placed between a pair of electrode layers. The organic compound layer contains a light-emitting layer, and the organic EL devices emit, from a light-extraction surface, the light having been emitted from the light-emitting layer. In this case, these devices suffer low light-extraction efficiency, since the totally reflected components (i.e., light entering at an angle higher than the critical angle) cannot be extracted at the interfaces formed between the organic compound layer and the light-extraction surface or the electrode layers.

For this reason, some organic EL devices that have a light-extraction member (e.g., a lens) on a light path have been proposed to improve the light-extraction efficiency. In these organic EL devices, the lens controls the path of the light emitted from the light-emitting layer and makes the light to be emitted from the light-extraction surface.

For example, Japanese Patent Application Laid-Open (JP-A) No. 2003-272873 discloses an organic EL head, which is composed of a substrate, a reflective layer provided on the substrate, an anode layer provided on the reflective layer, an organic EL light-emitting layer provided on the anode, and a thin metal layer having such a thickness as to transmit light. The organic EL head further contains a cathode to which the light-emitting layer adheres at one surface thereof, and on which a semi-transparent reflective layer is formed at the other surface thereof. In this organic EL head, the reflective layer and the semi-transparent reflective layer form a micro optical resonator (microcavity), and micro lenses are formed outside the semi-transparent reflective layer.

According to this proposal, the organic EL head is employed as a writing unit in image forming devices.

JP-A No. 2004-227940 discloses a display device containing a light-emitting layer and a lens layer. The light-emitting layer contains light-emitting elements placed between electrodes, and emits light when electric potential is applied to between the electrodes. The lens layer contains at least one microlens on the electrode through which the light, which has been emitted from the light-emitting element, is emitted. The microlens is placed at least within a distance that equals to the length of a side of the light-emitting element. The diameter of the microlens is greater than that of the light-emitting element.

The present inventors conducted extensive studies and have found, as described below, that light distribution (angular distribution of light) of an organic EL device greatly changes depending on the element design thereof, and that the structure of a lens (i.e., a light extraction component) suitable to light extraction depends on the light distribution.

The above points are not considered at all in conventional techniques. Thus, the light-extraction efficiency has not been optimized. That is, the most suitable diameter of a lens used in combination with an organic EL display part depends on the structure of the organic EL display part. In this regard, a combination of a lens and the structure of an organic EL display part has not been optimally designed. As a result, the light-extraction efficiency is not satisfactory, or image blur occurs when light propagates between the lens and the light-emitting layer.

### BRIEF SUMMARY OF THE INVENTION

The present invention aims to provide an organic EL device having high light-extraction efficiency, involving no image blur, and realizing low drive voltage, and to a design method thereof.

The present inventors conducted extensive studies in order to solve the above-described problems, and have found that a platinum complex compound containing a tetradentate ligand used in the present invention has high electron transportability, that use of this compound as a host material remarkably reduces drive voltage, and that a mixed host, composed of a platinum complex compound containing a tetradentate ligand and a hole transport host material, realizes both high light-emitting efficiency and reduction of the drive potential.

The present invention has been made based on these findings obtained by the present inventors. Means for solving the above existing problems are as follows.

<1> An organic electroluminescence device including:

an organic electroluminescence display part which includes an anode, a cathode and at least a light-emitting layer disposed therebetween, and

a lens which controls an optical path of light emitted from the light-emitting layer,

wherein the organic electroluminescence device has a ratio of A to B (A/B) of greater than 1, where A denotes a light-extraction efficiency in terms of front brightness when the lens is placed on a surface from which the light is extracted, and B denotes a light-extraction efficiency in terms of front brightness when the lens is not placed on the surface from which the light is extracted, and

wherein the organic electroluminescence device has a ratio of φ to a (φ/a) of 1.0 or greater, where a denotes the maximum length of a side of the light-emitting layer and φ denotes an effective diameter of the lens.

<2> The organic electroluminescence device according to <1> above, wherein the organic electroluminescence display part has a first order microcavity structure whose optical length L(λ) is 1λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.2 or greater, where a denotes the maximum length of a side of the light-emitting layer and φ denotes an effective diameter of the lens.

<3> The organic electroluminescence device according to <1> above, wherein the organic electroluminescence display part has a second order microcavity structure whose optical length L(λ) is 2λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.4 or greater, where a denotes the maximum length of a side of the light-emitting layer and φ denotes an effective diameter of the lens.

<4> The organic electroluminescence device according to <1> above, wherein the organic electroluminescence display part has a third order microcavity structure whose optical length L(λ) is 3λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.5 or greater, where a denotes the maximum length of a side of the light-emitting layer and φ denotes an effective diameter of the lens.

<5> The organic electroluminescence device according to <1> above, wherein the anode of the organic electroluminescence display part is a transparent electrode which has a reflectance of 10% or less when viewed from the light-emitting layer, wherein the organic electroluminescence device has a ratio of A to B (A/B) of greater than 1, where A denotes a light-extraction efficiency in terms of front brightness when the lens is placed on a surface from which the light is extracted and B denotes a light-extraction efficiency in terms of front brightness when the lens is not placed on the surface from which the light is extracted, and wherein the organic electroluminescence device has a ratio of φ to a (φ/a) of 1.0 or greater, where a denotes the maximum length of a side of the light-emitting layer and φ denotes an effective diameter of the lens.

<6> The organic electroluminescence device according to <1> above, wherein the ratio (φ/a) is 2.5 or greater.

<7> The organic electroluminescence device according to <1> above, wherein the ratio (φ/a) is 4.47 or less.

<8> The organic electroluminescence device according to <1> above, wherein the organic electroluminescence device has a ratio of d to φ (d/φ) of 0.1 or less, where d denotes a distance between the light-emitting layer and the lens and φ denotes an effective diameter of the lens.

<9> A design method of an organic electroluminescence device which includes an organic electroluminescence display part, containing an anode, a cathode and at least a light-emitting layer disposed therebetween, and a lens which controls an optical path of light emitted from the light-emitting layer, the design method including:

designing the organic electroluminescence device so as to have a ratio of A to B (A/B) of greater than 1, where A denotes a light-extraction efficiency in terms of front brightness when the lens is placed on a surface from which the light is extracted and B denotes a light-extraction efficiency in terms of front brightness when the lens is not placed on the surface from which the light is extracted, and to have a ratio of φ to a (φ/a) of 1.0 or greater, where a denotes the maximum length of a side of the light-emitting layer and φ denotes an effective diameter of the lens.

The present invention can provide an organic EL device involving no image blur, having high light-extraction efficiency, and realizing low drive voltage, and to a design method thereof. These can solve the existing problems pertinent in the art.

### BRIEF DESCRIPTION OF THE DRAWINGS

FIG. 1 is a diagram illustrating the relationship between the numerical aperture and the ratio (φ/a).

FIG. 2 is a schematic cross-sectional diagram illustrating an example of an organic EL device of the present invention.

FIG. 3 is a schematic cross-sectional diagram illustrating another example of an organic EL device of the present invention.

FIG. 4 illustrates an example of the light distribution of an organic EL element.

FIG. 5 illustrates another example of the light distribution of an organic EL element.

FIG. 6 illustrates still another example of the light distribution of an organic EL element.

FIG. 7 illustrates yet another example of the light distribution of an organic EL element.

FIG. 8 is a diagram illustrating the state of light emission when a light-emitting part is disposed on the center of a lens.

FIG. 9 is a diagram illustrating the state of light emission when a light-emitting part is disposed off the center of a lens.

FIG. 10 is a schematic diagram of the organic EL device used for the evaluation experiments on light-extraction efficiency in Example 1.

FIG. 11 is a top view of the organic EL device used for the evaluation experiments on light-extraction efficiency in Example 1.

FIG. 12 is a graph of the relationship between light-extraction efficiency in terms of front brightness and effective diameter of a lens in Example 1.

FIG. 13 is a graph of the relationship between light-extraction efficiency in terms of integral intensity and effective diameter of a lens in Example 1.

FIG. 14 is a schematic diagram of the organic EL device used for the evaluation experiments on light-extraction efficiency in Example 2.

FIG. 15 is a top view of the organic EL device used for the evaluation experiments on light-extraction efficiency in Example 2.

FIG. 16 is a graph of the relationship between light-extraction efficiency in terms of front brightness and effective diameter of a lens in Example 2.

FIG. 17 is a graph of the relationship between the light-extraction efficiency in terms of integral intensity and effective diameter of a lens in Example 2.

FIG. 18 illustrates a state where lenses are arranged over RGB 3 pixels.

FIG. 19 illustrates a state where lenses are arranged over RGB 3 pixels.

FIG. 20 illustrates a way to obtain value a (the maximum length of a side) when a pixel is rectangle.

FIG. 21A is a top view of a state where a lens is disposed over a square pixel.

FIG. 21B is a side view of a state where a lens is disposed over a square pixel.

FIG. 22A is a top view of a state where a lens is disposed over a rectangular pixel.

FIG. 22B is a side view of a state where a lens is disposed over a rectangular pixel.

FIG. 23A is a top view of a state where a lens is disposed over a circular pixel.

FIG. 23B is a side view of a state where a lens is disposed over a circular pixel.

FIG. 24A is a top view of a state where a lens is disposed over a triangular pixel.

FIG. 24B is a side view of a state where a lens is disposed over a triangular pixel.

### DETAILED DESCRIPTION OF THE INVENTION

### (Organic EL Device and Design Method Thereof)

An organic EL device of the present invention includes at least an organic EL display part and a lens placed on a surface from which light is emitted (a light-extraction surface). The organic EL device may also include a substrate, a barrier layer and other members, as required.

A design method of the present invention is a method of designing the organic EL device of the present invention so as to have a ratio of A to B (A/B) of greater than 1, where A denotes a light-extraction efficiency in terms of front brightness when the lens is placed on a surface from which the light is extracted and B denotes a light-extraction efficiency in terms of front brightness when the lens is not placed on the surface from which the light is extracted, and to have a ratio of φ to a (φ/a) of 1.0 or greater, where a denotes the maximum length of a side of the light-emitting layer and φ denotes an effective diameter of the lens.

The organic EL device of the present invention and the design method thereof are described in detail below.

In the present invention, first, the ratio of A to B (A/B) is greater than 1, where A denotes a light-extraction efficiency in terms of front brightness when the lens is placed on the light-extraction surface, and B denotes a light-extraction efficiency in terms of front brightness when the lens is not placed on the light-extraction surface.

The fact that the ratio (A/B) is greater than 1 means that the light-extraction efficiency A in terms of front brightness when the lens is placed on the light-extraction surface is higher than the light-extraction efficiency B in terms of front brightness when the lens is placed on the light-extraction surface. In other words, the lens attached on the light-extraction surface improves the light-extraction efficiency in terms of front brightness, thus improving the brightness viewed from the front.

The light-extraction efficiency is evaluated in terms of front brightness, instead of integral intensity. This is because, considering the applications to organic EL displays, the front brightness is more important as an index of power consumption, which is defined as power required for obtaining a certain front brightness.

Although the ratio (A/B) is not particularly limited and any ratio may be selected so long as it is greater than 1, the ratio is preferably 1.5 or greater, more preferably 2.0 or greater. When the ratio (A/B) is 1 or less, the provision of such a lens as a light-extracting component exhibits no effects, resulting in that the object of the present invention cannot be achieved in some cases.

The light-extraction efficiency in terms of front brightness may be measured with, for example, a spectroradiometer (SR-3, Topcon Techno house Co.).

In the present invention, second, the ratio of φ to a (φ/a) is 1.0 or greater in light-extraction efficiency in terms of front brightness, where a denotes the maximum length of a side of the light-emitting layer, and φ denotes an effective diameter of the lens.

In the light-extraction efficiency in terms of front brightness, the fact that the ratio (φ/a) is 1.0 or greater means that the effective diameter φ of the lens is equal to or greater than the maximum length “a” of a side of a light-emitting layer, and that the size (area) of the lens is equal to or greater than the size (area) of the light-emitting layer.

Here, the maximum length of a side of the light-emitting layer may vary with its shape and any length may be selected. However, the longest side should be chosen if the sides have different lengths (e.g., in the case of a rectangle light-emitting layer). If all sides are in equal length (e.g., in the case of a square light-emitting layer), the longest side may be any side.

The effective diameter of the lens is the diameter of the part of the lens that effectively functions as such. Therefore, if the whole lens effectively functions as a lens, the effective diameter thereof is equivalent to the diameter thereof.

With regard to the light-extraction efficiency in terms of front brightness, the ratio of φ to a (φ/a) is 1.0 or greater, where a denotes the maximum length of a side of the light-emitting layer, and φ denotes an effective diameter of the lens. The ratio (φ/a) is preferably 1.2 or greater. The ratio (φ/a) is more preferably 2.5 or greater, around which the improving effect on the light-extraction efficiency by virtue of an increase in the effective diameter of a lens reaches the maximum level.

When the ratio (φ/a) is less than 1.0, the light-extraction efficiency fails to increase, since the area which is not covered with the lens becomes large.

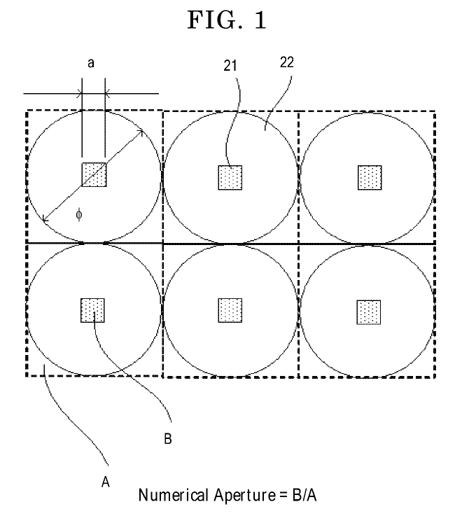

When the effective diameter φ of the lens is much larger than the maximum length of a side of the light-emitting layer, the numerical aperture decreases in organic EL displays. As shown in FIG. 1, the numerical aperture (B/A) of a known, common EL display is about 5%, at which the ratio (φ/a) is 4.47 when lenses are placed on a glass substrate in square grid. Thus, the upper limit of the ratio (φ/a) is preferably 4.47. When the ratio (φ/a) becomes greater than 4.47, minimally required brightness for practical use may not be ensured.

### —Light-Extraction Efficiency in Terms of Integral Intensity—

As described above, in the present invention, the ratio of A to B (A/B) is greater than 1 and the ratio (φ/a) is 1.0 or greater with regard to the light-extraction efficiency in terms of front brightness. In addition, preferably, the ratio of C to D (C/D) is greater than 1 and the ratio of φ to a (φ/a) is 1.5 or greater (more preferably 2.0 or greater) with regard to the light-extraction efficiency in terms of integral intensity. Here, C denotes a light-extraction efficiency in terms of integral intensity when the lens is placed on the light-extraction surface, D denotes a light-extraction efficiency in terms of integral intensity when the lens is not placed on the light-extraction surface, φ denotes an effective diameter of the lens, and a denotes the maximum length of a side of the light-emitting layer. The upper limit of the ratio (φ/a) is preferably 4.47.

The fact that the ratio (C/D) is greater than 1 means that the light-extraction efficiency in terms of integral intensity is improved as a result of attachment of the lens. Even when the light-extraction efficiency in terms of front brightness is high, the brightness viewed at oblique angles may not be sufficient when the light-extraction efficiency in terms of integral intensity is low.

The light-extraction efficiency in terms of integral intensity may be measured by, for example, measuring light intensities with and without lens using an integrating sphere and comparing the measured light intensities with each other.

The ratios (φ/a) regarding the light-extraction efficiencies in terms of front brightness and integral intensity may vary with, for example, the structure of an organic EL display part (organic EL element) and the effective diameter of the lens. Thus, in the present invention, the light-extraction efficiencies can be optimized using a lens suitable to the structure of an organic EL display part.

The structure of the organic EL display part is not particularly limited, and any structure may be selected according to the intended purpose. Examples thereof include (1) the reflectance of an electrode (i.e., an anode) on the light-emitting side of an organic EL display device, (2) an optical length of a microcavity structure, and (3) a bottom-emission type or top-emission type.

Regarding the electrode on the light-emitting side (i.e., an anode) of the organic EL display part (described in (1) above), in the bottom-emission type, a transparent or a semi-transmissive electrode may be used. Here, the transparent electrode has a reflectance of 10% or less when viewed from a light-emitting layer (e.g., an ITO electrode), and the semi-transmissive electrode has a reflectance more than 10% when viewed from a light-emitting layer (e.g., an Ag electrode). When the transparent electrode is employed as the anode, the microcavity structure cannot be formed as light reflection is weak. When the semi-transmissive electrode is used as the anode, the microcavity structure can be formed.

Regarding the top-emission type, a semi-transmissive electrode, which has a reflectance more than 10% when viewed from a light-emitting layer, is used as the electrode on the light-emission side (i.e., an anode) for forming a microcavity structure.

The optical length of the microcavity structure described in above (2) may be appropriately adjusted by varying the thickness of the organic compound layer between the anode and the cathode constituting the organic EL display part. The organic compound layer is not particularly limited and any layer may be selected according to the intended purpose. Examples thereof include a hole transport layer, a hole injection layer, a light-emitting layer, an electron transport layer and an electron injection layer.

Here, the microcavity structure means a structure in which light reflected on a semi-transmissive reflective layer at the light emission side interferes with light reflected on a reflective layer at the opposite side to the light emission side.

The optical length (optical distance) L of the microcavity structure is expressed by L=2×Σnᵢdᵢ (where i is an integer of 1 to i (the number of layers)) and by a phase shift through reflection. The optical length (optical distance) L is the sum of the products of d and n, where d denotes the thickness of each layer formed between an anode and a cathode, and n denotes a refractive index of each layer.

The optical length L and the wavelength of emitted light λ have the relationship: optical length L(λ)=(m=1: first order, m=2: second order, and m=3: third order). The optical length L(λ) is expressed by the following mathematical equation:

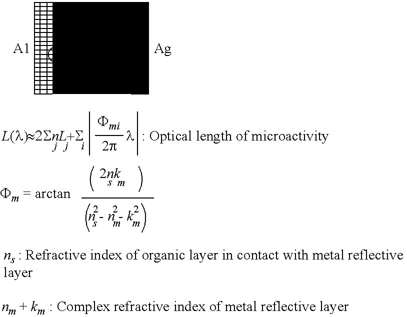

In the above equation, L(λ) denotes an optical length [=2Σnⱼdⱼ+ΣABS(φmᵢλ2π)], where λ denotes a wavelength of emitted light, i denotes a suffix indicating a metal reflective layer, and j denotes a suffix indicating the other layers between the metal layers than the metal reflective layer (e.g., organic layers and dielectric layers).

The fact that the microcavity structure is first order means that the optical length L(λ)is 1λ, (where λ denotes a wavelength of emitted light), which is the minimum optical length to satisfy the conditions under which lights making round-trips between the metal reflective layers strengthen each other.

The fact that the microcavity structure is second order means that the optical length L(λ) is 2λ (where λ denotes a wavelength of emitted light), which is the second shortest optical length to satisfy the conditions under which lights making round-trips between the metal reflective layers strengthen each other.

The fact that the microcavity structure is third order means that the optical length L(λ) is 3λ (where λ denotes a wavelength of the emitted light), which is the third shortest optical length to satisfy the conditions under which lights making round-trips between the metal reflective layers strengthen each other.

### First Embodiment

In a first embodiment, an organic EL display part has a first order microcavity structure whose optical length L(λ) is 1λ, (where λ denotes a wavelength of emitted light). The structure may be of a bottom-emission or top-emission type.

In this first embodiment, preferably, the ratio of A to B (AM) is greater than 1 and the ratio of φ to a (φ/a) is 1.2 or greater, where A denotes a light-extraction efficiency in terms of front brightness when the lens is placed on the light-extraction surface, B denotes a light-extraction efficiency in terms of front brightness when the lens is not placed on the light-extraction surface, φ denotes an effective diameter of the lens, and a denotes the maximum length of a side of the light-emitting layer. The ratio (φ/a) is more preferably 1.6 or greater, still more preferably 2.5 or greater. The upper limit of the ratio (φ/a) is preferably 4.47.

Also, preferably, the ratio of C to D (C/D) is greater than 1 and the ratio of φ to a (φ/a) is 1.6 or greater, where C denotes a light-extraction efficiency in terms of integral intensity when the lens is placed on the light-extraction surface, D denotes a light-extraction efficiency in terms of integral intensity when the lens is not placed on the light-extraction surface, φ denotes an effective diameter of the lens, and a denotes the maximum length of a side of the light-emitting layer. The ratio (φ/a) is more preferably 2.0 or greater. The upper limit of the ratio (φ/a) is preferably 4.47.

### Second Embodiment

In a second embodiment, an organic EL display part has a second order microcavity structure whose optical length L(λ) is 2λ, (where λ denotes a wavelength of emitted light). The structure may be of a bottom-emission or top-emission type.

In this second embodiment, preferably, the ratio of A to B (A/B) is greater than 1 and the ratio of φ to a (φ/a) is 1.4 or greater, where A denotes a light-extraction efficiency in terms of front brightness when the lens is placed on the light-extraction surface, B denotes a light-extraction efficiency in terms of front brightness when the lens is not placed on the light-extraction surface, φ denotes an effective diameter of the lens, and a denotes the maximum length of a side of the light-emitting layer. The ratio (φ/a) is more preferably 1.8 or greater, still more preferably 2.5 or greater. The upper limit of the ratio (φ/a) is preferably 4.47.

Also, preferably, the ratio of C to D (C/D) is greater than 1 and the ratio of φ to a (φ/a) is 1.2 or greater, where C denotes a light-extraction efficiency in terms of integral intensity when the lens is placed on the light-extraction surface, D denotes a light-extraction efficiency in terms of integral intensity when the lens is not placed on the light-extraction surface, φ denotes an effective diameter of the lens, and a denotes the maximum length of a side of the light-emitting layer. The ratio (φ/a) is more preferably 1.6 or greater, still more preferably 2.0 or greater. The upper limit of the ratio (φ/a) is preferably 4.47.

### Third Embodiment

In a third embodiment, an organic EL display part has a third order microcavity structure whose optical length L(λ) is 3λ (where λ denotes a wavelength of emitted light). The structure may be of a bottom-emission or top-emission type.

In this third embodiment, preferably, the ratio of A to B (A/B) is greater than 1 and the ratio of φ to a (φ/a) is 1.5 or greater, where A denotes a light-extraction efficiency in terms of front brightness when the lens is placed on the light-extraction surface, B denotes a light-extraction efficiency in terms of front brightness when the lens is not placed on the light-extraction surface, φ denotes an effective diameter of the lens, and a denotes the maximum length of a side of the light-emitting layer. The ratio (φ/a) is more preferably 2.0 or greater, still more preferably 2.5 or greater. The upper limit of the ratio (φ/a) is preferably 4.47.

Also, preferably, the ratio of C to D (C/D) is greater than 1 and the ratio of φ to a (φ/a) is 1.3 or greater, where C denotes a light-extraction efficiency in terms of integral intensity when the lens is placed on the light-extraction surface, D denotes a light-extraction efficiency in terms of integral intensity when the lens is not placed on the light-extraction surface, φ denotes an effective diameter of the lens, and a denotes the maximum length of a side of the light-emitting layer. The ratio (φ/a) is more preferably 2.0 or greater. The upper limit of the ratio (φ/a) is preferably 4.47.

### Fourth Embodiment

In a fourth embodiment, the anode of the organic EL display part is a transparent electrode (e.g., an ITO electrode) which has a reflectance of 10% or less when viewed from the light-emitting layer. The structure is of a bottom-emission type.

In this fourth embodiment, preferably, the ratio of A to B (AM) is greater than 1 and the ratio of φ to a (φ/a) is 1.0 or greater, where A denotes a light-extraction efficiency in terms of front brightness when the lens is placed on the light-extraction surface, B denotes a light-extraction efficiency in terms of front brightness when the lens is not placed on the light-extraction surface, φ denotes an effective diameter of the lens, and a denotes the maximum length of a side of the light-emitting layer. The ratio (φ/a) is more preferably 1.5 or greater, still more preferably 2.5 or greater. The upper limit of the ratio (φ/a) is preferably 4.47.

Also, preferably, the ratio of C to D (C/D) is greater than 1 and the ratio of φ to a (φ/a) is 1.2 or greater, where C denotes a light-extraction efficiency in terms of integral intensity when the lens is placed on the light-extraction surface, D denotes a light-extraction efficiency in terms of integral intensity when the lens is not placed on the light-extraction surface, φ denotes an effective diameter of the lens, and a denotes the maximum length of a side of the light-emitting layer. The ratio (φ/a) is more preferably 2.0 or greater. The upper limit of the ratio (φ/a) is preferably 4.47.

In the present invention, the ratio of d to φ (d/φ) is preferably 0.1 or less, where d denotes a distance between the light-emitting layer and the lens, and φ denotes an effective diameter of the lens. The ratio (d/φ) is more preferably 0.05 or less. When the ratio (d/φ) becomes greater than 0.1, image blur may occur.

### <Organic EL Display Part >

The organic EL display part (organic EL element) contains an anode, a cathode and at least a light-emitting layer therebetween. If necessary, the organic EL display part may further contain a hole injection layer, a hole transport layer, an electron injection layer, an electron transport layer, and other layers. Each of the layers may have other functions than its intrinsic function, and may be made of various materials.

The organic EL display part is composed as a pixel of red (R), green (G), or blue (B).

Any known constitution may be applied to the constitution of these pixels, such as the tricolor light emission method, as described on pp. 33 to 37 of the September issue of “Display Monthly” (2000). In this method, pixels containing a light-emitting layer that emit red, green, or blue light are formed and arranged.

### —Anode—

The anode supplies holes to a hole injection layer, a hole transport layer, and a light-emitting layer. The anode may be made of a metal, an alloy, a metal oxide, a conductive compound, or a mixture thereof. Preferably, the material has a work function of 4 eV or greater. Specific examples thereof include conductive metal oxides (e.g., tin oxide, zinc oxide, indium oxide and indium tin oxide (ITO)), metals (e.g., gold, silver, chromium and nickel), mixtures or laminates of these metals and these conductive metal oxides, inorganic conductive materials (e.g., copper iodide and copper sulfide) and organic conductive materials (e.g., polyaniline, polythiophene and polypyrrole), as well as laminates of these materials and ITO. Among them, conductive metal oxides are preferred. In particular, ITO is preferred from the viewpoint of exhibiting high productivity, high conductivity and high transparency.

The thickness of the anode is not particularly limited and any thickness may be selected depending on the material. The thickness is preferably 10 nm to 50 μm, more preferably 50 nm to 1 μm, still more preferably 100 nm to 500 nm.

The anode is generally formed on, for example, a soda-lime glass substrate, an alkali-free glass substrate, or a transparent resin substrate. When a glass substrate is used, an alkali-free glass substrate is preferably used to reduce ions eluted from the glass. When a soda-lime glass is used, it is preferably barrier-coated with silica or the like.

The thickness of the substrate is not particularly limited, so long as it is sufficient to maintain mechanical strength. When a glass substrate is used, the thickness thereof is preferably 0.2 mm or greater, more preferably 0.7 mm or greater.

The transparent resin substrate may be a barrier film. The barrier film is a film composed of a plastic support and a gas-impermeable barrier layer placed thereon. Such barrier films include films vapor-deposited with silica oxide or aluminum oxide (Japanese Patent Application Publication (JP-B) No. 53-12953, and JP-A No. 58-217344), films having an organic-inorganic hybrid coating layer (JP-A Nos. 2000-323273 and 2004-25732), films having an inorganic layer compound (JP-A No. 2001-205743), films on which an inorganic material is laminated (JP-A Nos. 2003-206361 and 2006-263989), films on which organic and inorganic layers are alternately laminated (JP-A No. 2007-30387, U.S. Pat. No. 6,413,645, Affinito et al., Thin Solid Films (1996) pp. 290-291), and films on which organic and inorganic layers are continuously laminated (U.S. Patent Application Laid-Open No. 2004-46497).

As for the fabrication of the anode, various methods may be employed depending on the materials. When the anode is an ITO film, it is formed by, for example, an electron-beam method, sputtering, vapor deposition through resistive heating, a chemical method (such as a sol-gel method), or application of a dispersion of indium tin oxide. The anode may be subjected to treatments such as washing to reduce the drive voltage of a display device, or increase the light-emitting efficiency. For example, a UV-ozone treatment is effectively performed for the ITO film.

### —Cathode—

The cathode supplies electrons to, for example, an electron injection layer, an electron transport layer, and a light-emitting layer. The cathode is selected considering, for example, ionization potential, stability, and adhesiveness to the adjacent layers, such as the electron injection layer, the electron transport layer, and the light-emitting layer.

The cathode may be made of a metal, an alloy, a metal oxide, a conductive compound, or mixtures thereof. Specific examples thereof include alkali metals (e.g., Li, Na and K) and fluorinated compounds thereof, alkaline earth metals (e.g., Mg and Ca) and fluorinated compounds thereof, gold, silver, lead, aluminum, alloys/mixed metals of sodium and potassium, alloys/mixed metals of lithium and aluminum, alloys/mixed metals of magnesium and silver, and rare earth metals such as indium and ytterbium. Among them, materials having a work function of 4 eV or less are preferred. Particularly preferred are aluminum, alloys/mixed metals of lithium and aluminum, and alloys/mixed metals of magnesium and silver.

The thickness of the cathode is not particularly limited and any thickness may be selected depending on the material. It is preferably 10 nm to 5 μm, more preferably 50 nm to 1 μm, particularly preferably 100 nm to 1 μm.

As for the fabrication of the cathode, various methods may be employed, including an electron-beam method, sputtering, vapor deposition through resistive heating, and a coating method. An elemental metal or two or more components may be vapor-deposited. Furthermore, a metal alloy electrode may be formed by vapor-depositing a plurality of metals simultaneously or an alloy prepared in advance.

The sheet resistance of the anode or the cathode is preferably low; i.e., several hundreds Ω/sq. or lower.

### —Light-Emitting Layer—

The material of the light-emitting layer is not particularly limited and any material may be selected according to the intended purpose. Examples thereof include those capable of forming a layer which has functions of, when an electric potential is applied, receiving holes from an anode, a hole injection layer, and a hole transport layer, and receiving electrons from a cathode, an electron injection layer, and an electron transport layer, which has a function of transporting injected charges, and which provides a place for the recombination of electrons and holes causing light emission.

The material of the light-emitting layer is not particularly limited and any material may be appropriately selected according to the intended purpose. Examples thereof include benzoxazole derivatives, benzimidazole derivatives, benzothiazole derivatives, styrylbenzen derivatives, polyphenyl derivatives, diphenylbutadiene derivatives, tetraphenyl butadiene derivatives, naphthalimide derivatives, coumarin derivatives, perylene derivatives, perinone derivatives, oxadiazol derivatives, aldazine derivatives, pyralidine derivatives, cyclopentadiene derivatives, bis(styryl)anthracene derivatives, quinacridone derivatives, pyrrolopyridine derivatives, thiadiazolepyridine derivatives, styrylamine derivatives, aromatic dimethyldine compounds, various metal complexes such as metal/rare metal complexes of 8-quinolinol derivatives, and polymer compounds such as polythiophene, polyphenylene, and polyphenylene vinylene. These may be used individually or in combination.

The thickness of the light-emitting layer is not particularly limited and any thickness may be selected according to the intended purpose. The thickness is preferably 1 nm to 5 μm, more preferably 5 nm to 1 μm, still more preferably 10 nm to 500 nm.

The method of forming the light-emitting layer is not particularly limited and any method may be appropriately selected according to the intended purpose. Preferred examples thereof include vapor deposition through resistive heating, electron-beam methods, sputtering, molecular-layering methods, and coating methods (e.g., spin-coat methods), cast methods and dip-coat methods) and LB methods. Among them, vapor deposition through resistive heating and coating methods are particularly preferred.

### —Hole Injection Layer and Hole Transport Layer—

The materials for the hole injection layer and hole transport layer are not particularly limited. Any material may be appropriately selected according to the intended purpose, so long as it possesses any of the following functions: a function of injecting holes from an anode, a function of transporting holes, and a function of blocking electrons injected from a cathode.

Examples of the materials include carbazole derivatives, triazole derivatives, oxazole derivatives, oxidiazole derivatives, imidazole derivatives, poly(aryl alkane)derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylben derivatives, silazane derivatives, aromatic tertiary amine compounds, styrylamine compounds, aromatic dimethylidine-derived compounds, porphyrin-derived compounds, polysilane-derived compounds, poly(N-vinylcarbazol)derivatives, aniline-derived copolymers, thiophene oligomers, and conductive polymeric oligomers (e.g., polythiophene). These may be used individually or in combination.

The hole injection layer and hole transport layer may be of either single-layer structure made of one or more of the aforementioned materials, or multi-layer structure made of a plurality of layers identical to or different from one another in composition.

Examples of the method of forming the hole injection layer and hole transport layer include vapor deposition methods, LB methods, and methods by coating a solution or dispersion liquid prepared by dissolving or dispersing the aforementioned hole injection/transport materials in a solvent (e.g., spin-coat methods, cast methods and dip-coat methods). In the cases of these coating methods, the hole injection/transport materials may be dissolved or dispersed in a solvent together with a resin component.

The resin component is not particularly limited and any resin may be appropriately selected according to the intended purpose. Examples thereof include polyvinylchloride resins, polycarbonate resins, polystyrene resins, polymethylmethacrylate resins, polybutylmethacrylate resins, polyester resins, polysulfone resins, polyphenylene oxide resins, polybutadiene, poly(N-vinylcarbazol)resins, hydrocarbon resins, ketone resins, phenoxy resins, polyamide resins, ethyl cellulose, vinyl acetate resins, ABS resins, polyurethane resins, melamine resins, unsaturated polyester resins, alkyd resins, epoxy resins, and silicone resins. They may be used individually or in combination.

The thickness of the hole injection layer or the hole transport layer is not particularly limited and any thickness may be appropriately selected according to the intended purpose. The thickness is preferably 1 nm to 5 μm, more preferably 5 nm and 1 μm, still more preferably 10 nm to 500 nm.

### —Electron Injection Layer and Electron Transport Layer—

The materials for the electron injection layer and electron transport layer are not particularly limited. Any material may be appropriately selected according to the intended purpose, so long as it possesses any of the following functions: a function of injecting electrons from a cathode, a function of transporting electrons, and a function of blocking holes injected from an anode.

Examples of the materials for the electron injection layer and electron transport layer include triazole derivatives, oxazole derivatives, oxidiazole derivatives, fluorenone derivatives, anthraquinodimethane derivatives, anthrone derivatives, diphenylquinone derivatives, thiopyran dioxide derivatives, carbodiimide derivatives, fluorenylidene methane derivatives, distyrylpyradine derivatives, heterocyclic tetracarboxylic anhydride (e.g., naphthalene and perylene), phthalocyanine derivatives, and various metal complexes represented by metal complexes of 8-quinolyl derivatives, metal phthalocyanine, and metal complexes containing benzoxazole or benzothiazole as a ligand. These may be used individually or in combination.

The electron injection layer and the electron transport layer may be of either single-layer structure made of one or more of the aforementioned materials, or multi-layer structure made of a plurality of layers identical to or different from one another in composition.

Examples of the method of forming the electron injection layer and the electron transport layer include vapor-deposition methods, LB methods, and methods by coating a solution or dispersion liquid prepared by dissolving or dispersing the aforementioned hole injection/transport materials in a solvent (e.g., spin-coat methods, cast methods and dip-coat methods). In the cases of these coating methods, the hole injection/transport materials may be dissolved or dispersed in a solvent together with a resin component. As for the resin component, the resins exemplified for the hole injection/transport layers may be used.

The thickness of the electron injection layer or the electron transport layer is not particularly limited and any thickness may be appropriately selected according to the intended purpose. The thickness is preferably 1 nm to 5 μm, more preferably 5 nm to 1 μm, still more preferably 10 nm to 500 nm.

### <Lens>

The lens has a function of controlling the path of the light emitted from a light-emitting layer, with being placed on the light-extraction surface.

Examples of the light-extraction surface include a glass substrate or the like in the case of a bottom emission type, and a barrier layer or the like in the case of a top-emission type.

The shape, arrangement, size and material of the lens are not particularly limited and may be appropriately selected according to the intended purpose. Examples of the shape include spherical, semi-spherical, elliptic, and trapezoidal. Of these, a semi-spherical lens is particularly preferred from the viewpoint of exhibiting an improved front brightness.

Examples of the arrangement include square grid and honeycomb.

Examples of the material include transparent resins, glass, transparent crystals, and transparent ceramics.

As to the size, when the lens is a semi-spherical lens, the effective diameter is preferably 10 μm to 1,000 μm, more preferably 20 μm to 200 μm.

The method of forming the lens is not particularly limited and any method may be appropriately selected according to the intended purpose. Examples thereof include inkjet methods, imprint methods and photolithography methods.

In the imprint method, a lens may be formed on an organic EL element through the process including applying a composition containing a releasing agent and a UV-curable resin on a transparent mold, pressure-bonding the transparent mold onto an organic EL element, irradiating the organic EL element with UV light, and removing the transparent mold.

### —Barrier Layer—

The barrier layer is not particularly limited and may be appropriately selected according to the intended purpose, so long as it has a function of preventing permeation of atmospheric oxygen, moisture, nitrogen oxides, sulfur oxides, ozone, and the like.

The material for the barrier layer is not particularly limited and any material may be appropriately selected according to the intended purpose. Examples thereof include SiN or SiON.

The thickness of the barrier layer is not particularly limited and any thickness may be appropriately selected according to the intended purpose. The thickness of the barrier layer is preferably 5 nm to 1,000 nm, more preferably 7 nm to 750 nm, particularly preferably 10 nm to 500 nm. When the thickness is less than 5 nm, the barrier function of preventing permeation of atmospheric oxygen and moisture may be insufficient. Whereas when the thickness is greater than 1,000 nm, the light transmittance decreases, potentially degrading transparency.

As to optical characteristics of the barrier layer, the light transmittance is preferably 80% or more, more preferably 85% or more, still more preferably 90% or more.

The method of forming the barrier layer is not particularly limited and any method may be appropriately selected according to the intended purpose. Examples thereof include CVD methods and vacuum-deposition methods.

### —Substrate—

The shape, structure and size of the substrate may be appropriately selected. In general, the substrate is preferably a plate-like substrate. The structure of the substrate may be single- or multi-layered, and may be made of one or more materials. The substrate may be a colorless or colored transparent substrate. However, a colorless transparent substrate is preferred since it does not scatter or attenuate the light emitted from the light-emitting layer.

The material for the substrate is not particularly limited and any material may be appropriately selected according to the intended purpose. Examples thereof include inorganic materials such as yttria-stabilized zirconia (YSZ) and glass, and organic materials such as polyester resins (e.g., polyethylene telephtharate resins, polybutylene phthalate resins and polyethylene naphthalate resins), polystyrene resins, polycarbonate resins, polyether sulfonate resins, polyarylate resins, polyimide resins, polycycloolefine resins, norbornene resins and poly(chlorotrifluoroethylene)resins. These may be used individually or in combination.

When a glass substrate is used, an alkali-free glass substrate is preferably used to reduce ions eluted from the glass. When a soda-lime glass is used, it is preferably barrier-coated with silica or the like (e.g., a barrier-film substrate). A substrate of an organic material is preferred since it is superior in heat resistance, dimensional stability, solvent resistance, electrical insulating property and processibility.

When a thermoplastic substrate is used, it may be provided additionally with a hard-coat layer and an undercoat layer, as required.

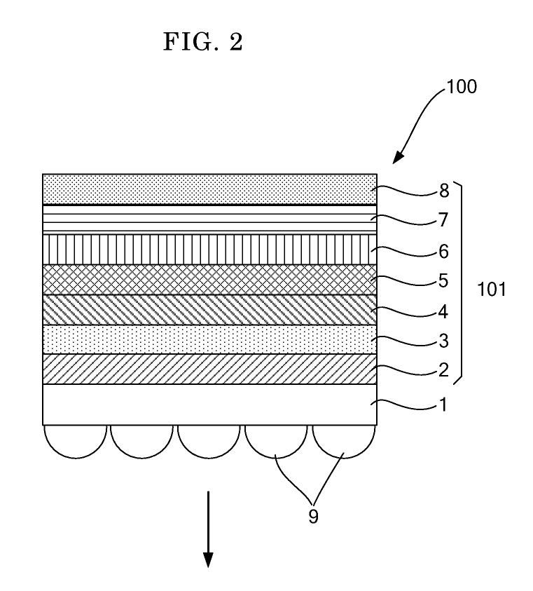

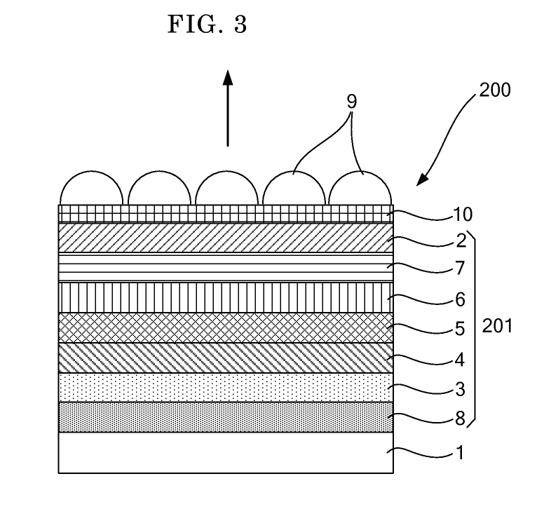

FIG. 2 is a schematic cross-section of a bottom-emission type organic EL device which is an example of the organic EL device of the present invention. FIG. 3 is a schematic cross-section of a top-emission type organic EL device which is another example of the organic EL device of the present invention.

A bottom-emission type organic EL device 100 illustrated in FIG. 2 has a glass substrate 1 and an organic EL display part 101 provided thereon (i.e., an anode 2, a hole injection layer 3, a hole transport layer 4, a light-emitting layer 5, an electron transport layer 6, an electron injection layer 7 and a cathode 8). Lenses 9 are formed on the glass substrate 1 as a light-extraction surface.

A top-emission type organic EL device 200 illustrated in FIG. 3 has a glass substrate 1 and an organic EL display part 201 provided thereon (i.e., an anode 8, a hole injection layer 3, a hole transport layer 4, a light-emitting layer 5, an electron transport layer 6, an electron injection layer 7 and a cathode 2). Further, a gas-barrier layer 10 is formed on the cathode 2, and lenses 9 are formed on the gas-barrier layer 10 as a light-extraction surface.

The “direction in which light is emitted” is a direction in which light is emitted from the light-emitting layer through the light-extraction surface toward the outside of the organic EL device. In the case of the bottom-emission type organic EL device 100 in FIG. 2, the direction in which light is emitted is a direction in parallel with the figure and toward the bottom from the light-emitting layer 5, as indicated by an arrow. In the case of the top-emission type organic EL device 200 in FIG. 3, the direction in which light is emitted is in parallel with the figure and toward the top from the light-emitting layer 5, as indicated by an arrow.

The organic EL device of the present invention may be a device which can display a full-color image. As a method for forming a full color-type display of the organic EL device of the present invention, there are known, for example, as described in “Monthly Display,” September 2000, pp. 33 to 37, a tricolor light emission method by arranging, on a substrate, organic EL devices emitting lights corresponding to three primary colors (blue color (B), green color (G) and red color (R)); a white color method by separating white light emitted from an organic EL device for white color emission into three primary colors through a color filter; and a color conversion method by converting a blue light emitted from an organic EL device for blue light emission into red color (R) and green color (G) through a fluorescent dye layer.

Further, by combining a plurality of layer structures emitting lights of different colors which are obtained by the above-described methods, plane-type light sources emitting lights of desired colors can be obtained. For example, there are exemplified white light-emitting sources obtained by combining blue and yellow light emitting devices, and white light-emitting sources obtained by combining blue, green and red light light-emitting devices.

The organic EL device of the present invention may be suitably used in various fields, such as computers, displays for automobiles, outdoor displays, domestic and commercial devices, domestic appliances, transportation-related displays, clock displays, calendar displays, luminescent screens and audio devices.

### Examples

The present invention will next be described by way of examples, which should not be construed as limiting the present invention thereto.

### Example 1

Four types of bottom-emission type organic EL elements (1) to (4) below were fabricated as follows.

<Fabrication of Organic EL Element (1) (wm=2) (Anode: Transparent Electrode (ITO)>

S-TIH6 (Ohara Inc.) (thickness: 0.2 mm and refractive index: 1.8) was provided as a glass substrate.

Next, ITO was vacuum-deposited on the glass substrate so as to have a thickness of 100 nm, to thereby form an anode. When viewed from the light-emitting layer, the reflectance of the formed ITO film was 2% and the light transmittance thereof was 97%.

Next, on the ITO film, 2-TNATA [4,4′,4″-tris(2-naphthylphenylamino)triphenylamine] and MnO₃ were vacuum-deposited at a ratio of 7:3 so as to have a thickness of 20 nm, to thereby form a hole injection layer.

Next, on the hole injection layer, 2-TNATA doped with F4-TCNQ (2,3,5,6-tetrafluoro-7,7,8,8-tetracyanoquinodimethane) at a concentration of 1.0% was vacuum-deposited so as to have a thickness of 141 nm, to thereby form a first hole transport layer.

Next, on the first hole transport layer, α-NPD [N,N′-(dinaphthylphenylamino)pyrene] was vacuum-deposited so as to have a thickness of 10 nm, to thereby form a second hole transport layer.

Next, on the second hole transport layer, a hole transport material A having the following structural formula was vacuum-deposited so as to have a thickness of 3 nm, to thereby form a third hole transport layer.

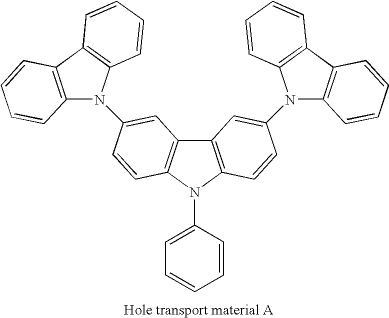

Next, on the third hole transport layer, CBP (4,4′-dicarbazole-biphenyl) serving as a host material and light-emitting material A having the following structural formula serving as a light-emitting material were co-deposited under vacuum at a ratio of 85:15 so as to have a thickness of 20 nm, to thereby form a light-emitting layer.

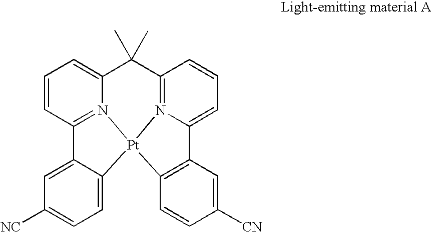

Next, on the light-emitting layer, BA1q (aluminum(III) bis(2-methyl-8-quinolinato)-4-phenylphenolate) was vacuum-deposited so as to have a thickness of 39 nm, to thereby form a first electron transport layer.

Next, on the first electron transport layer, BCP (2,9-dimethyl-4,7-diphenyl-1,10-phenanthrolin) was vacuum-deposited so as to have a thickness of 1 nm, to thereby form a second electron transport layer.

Next, on the second electron transport layer, LiF was vacuum-deposited so as to have a thickness of 1 nm, to thereby form an electron injection layer.

Next, on the electron injection layer, aluminum (Al) was vacuum-deposited so as to have a thickness of 100 nm, to thereby form a cathode.

Through the above procedure, organic EL element (1) was fabricated.

<Fabrication of Organic EL Element (2) (sm=1) (having a Microcavity Structure whose Optical Length is First Order)>

Organic EL element (2) was fabricated in the same manner as in the fabrication of organic EL element (1), except that a 20-nm thick Ag film was formed as an anode instead of the 100-nm thick ITO film, and that the thickness of the first electron transport layer was changed from 141 nm to 11 nm. When viewed from a light-emitting layer, the reflectance of the formed Ag film was 47% and the light transmittance thereof was 45%.

The thus-obtained organic EL element (2) was found to have a first order microcavity structure whose optical length L(λ) is 1λ (where λ denotes a wavelength of emitted light).

<Fabrication of Organic EL Element (3) (sm=2) (having a Microcavity Structure whose Optical Length is Second Order)>

Organic EL element (3) was fabricated in the same manner as in the fabrication of organic EL element (1), except that a 20-nm thick Ag film was formed as an anode instead of the 100-nm ITO film. When viewed from a light-emitting layer, the reflectance of the formed Ag film was 47% and the light transmittance thereof was 45%.

The thus-obtained organic EL element (3) was found to have a second order microcavity structure whose optical length L(λ) is 2λ (where λ denotes a wavelength of emitted light).

<Fabrication of Organic EL Element (4) (sm=3) (having a Microcavity Structure whose Optical Length is Third Order)>

Organic EL element (4) was fabricated in the same manner as in the fabrication of organic EL element (1), except that a 20-nm thick Ag film was formed as an anode instead of the 100-nm ITO film, and that the thickness of the first electron transport layer was changed from 141 nm to 271 nm. When viewed from a light-emitting layer, the reflectance of the formed Ag film was 47% and the light transmittance thereof was 45%.

The thus-obtained organic EL element (4) was found to have a third order microcavity structure whose optical length L(λ) is 3λ (where λ denotes a wavelength of emitted light).

The above-fabricated organic EL elements were optimized so as to emit green light (about 530 nm). In the organic EL elements, the value of a—the maximum length of a side of the light-emitting part (i.e., the light-emitting layer)—was 2 mm. Next, for each of the fabricated organic EL elements, a cylinder lens (refractive index=1.8) was attached to the light-extraction surface of the glass substrate with matching oil (refractive index=1.8). The lens had a sufficiently large diameter (radius: 10 mm). The light distribution of each organic EL element was measured as follows. Through this evaluation, the angular distribution of light in glass can be obtained.

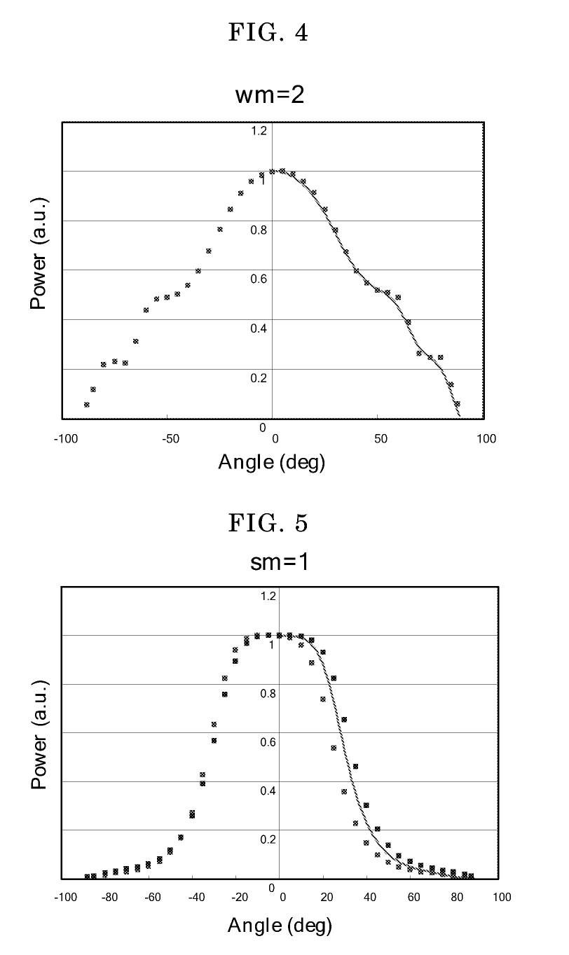

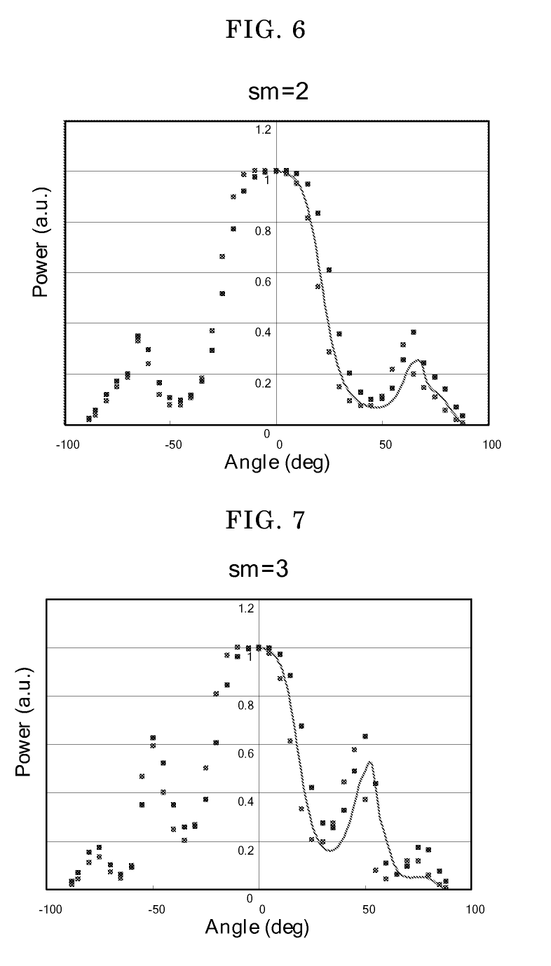

The light distribution of organic EL element (1) is shown in FIG. 4, the light distribution of organic EL element (2) in FIG. 5, the light distribution of organic EL element (3) in FIG. 6, and the light distribution of organic EL element (4) in FIG. 7.

### <Measuring Method of Light Distribution>

The light distribution was measured as follows. A silicone detector was attached to a goniometer, and each organic EL element was made to emit light. Then, the relationship between the angle of the goniometer and the signal of electrical potential corresponding to the light intensity from the detector was measured.

As is clear from FIGS. 4 to 7, the light distribution (angular distribution of light) in glass of each organic EL element depends greatly on their structure. Organic EL element (1) (FIG. 4) and organic EL element (3) (FIG. 6) differ in terms of only whether the anode is a transparent electrode (ITO) or a semi-transmissive electrode (Ag electrode). However, as shown in FIGS. 4 and 6, their light distributions in glass considerably differ from each other.

Similarly, organic EL element (2) (FIG. 5), organic EL element (3) (FIG. 6) and organic EL element (4) (FIG. 7) differ in the thickness of the hole transport layer and the optical length of the microcavity structure. As shown in FIGS. 5, 6 and 7, depending on whether the optical length of the microcavity structure was first, second, or third order, the light distribution (angular distribution of light) was found to be varied.

When no lens (light-extraction component) is attached on the light extraction surface of each organic EL element, the total reflection angle at the interface between glass and air is ±33°. Thus, no light is emitted to the air at an angle greater than this angle.

Next, description will be given with respect to the cases where a lens is attached to each organic EL element as a light-extraction component.

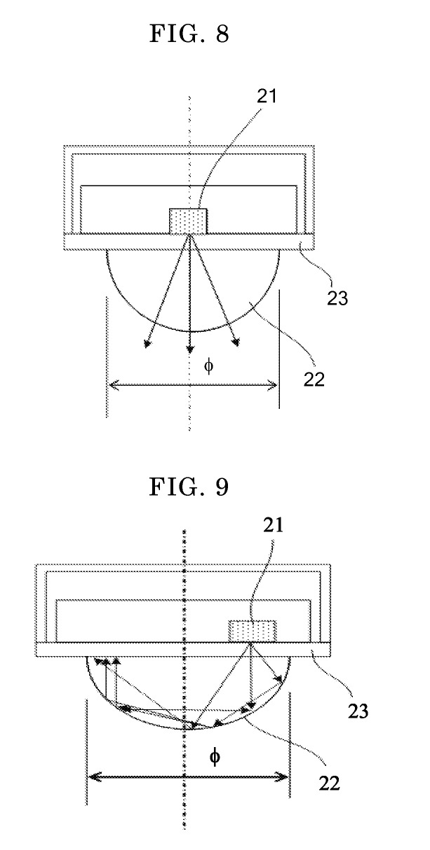

As shown in FIG. 8, when the light-emitting part (i.e., the light-emitting layer) 21 is close to the center of the lens 22, most of light is emitted to the air. On the other hand, as shown in FIG. 9, when the light-emitting part (i.e., the light-emitting layer) 21 is off the center of the lens 22, most of light is not emitted to the air and the total reflection is repeated within the lens.

Therefore, the more light in glass directed toward the front, the less light-extraction efficiency tends to be, as the amount of the total reflection increases.

Also, when the ratio of φ to a (φ/a), where φ denotes an effective diameter of the lens and a denotes the maximum length of a side of the light-emitting part (i.e., the light-emitting layer), is sufficiently large, most of light is emitted. However, when the ratio (φ/a) becomes closer to 1, the emitted light is expected to decrease.

However, considering light distribution, it is difficult to predict the quantitative behavior of organic EL elements. In fact, the behavior varies depending on the structure of an organic EL element. In particular, it is very difficult to predict when the ratio (φ/a) is close to 1, and thus, evaluation experiments of the light-extraction efficiency was carried out as follows.

### <Evaluation Experiments of Light-Extraction Efficiency>

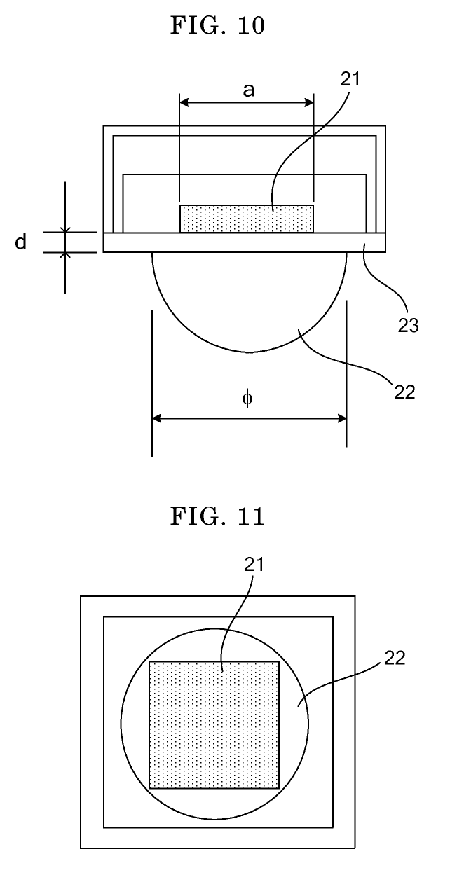

As shown in FIGS. 10 and 11, a semi-spherical lens 22 (refractive index=1.8) was attached onto the glass substrate 23 (serving as a light-extraction surface of an organic EL element) with matching oil (refractive index=1.8), to thereby fabricate organic EL devices. Then, φ (effective diameter of the lens) was changed from 0 mm to 8 mm.

The ratio (d/φ) of each organic EL device was 0.1, where d denotes a distance between the light-emitting layer 21 and the lens, and φ denotes an effective diameter of the lens.

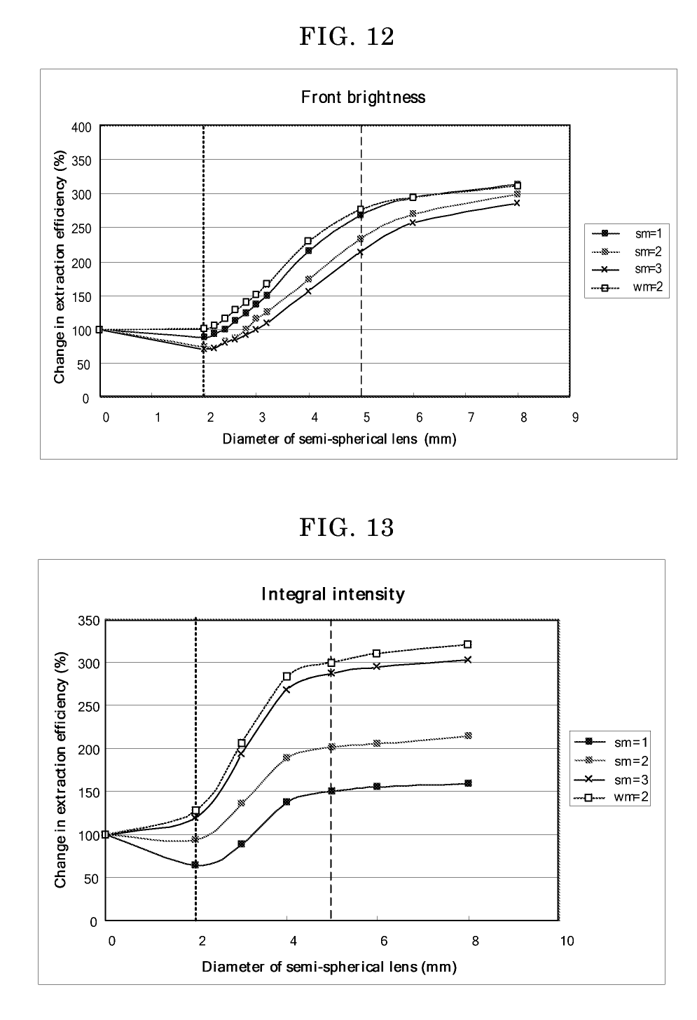

Each organic EL device was measured for light-extraction efficiency as follows. The light-extraction efficiency was measured in terms of both integral intensity and front brightness. The results are shown in FIGS. 12 (front brightness) and 13 (integral intensity).

### <Light-Extraction Efficiency>

The light-extraction efficiency was defined as a value calculated through dividing the front brightness measured with the attachment of the lens by that without the attachment of the lens, or a value calculated through dividing the integral intensity measured with the with the attachment of the lens by that without the attachment of the lens.

The integral intensity and front brightness were measured using spectroradiometer (SR-3, Topcon Techno house Co.).

As is clear from FIGS. 12 and 13, the light-extraction efficiencies in terms of integral intensity and front brightness were found to increase with increasing φ (effective diameter of the semi-spherical lens) and the ratio (φ/a). The increasing rate was found to depend on the structure of the organic EL element. Next, description will be given to the above-described finding for each organic EL element.

<Organic EL Element (1) (wm=2) (Anode: Transparent Electrode (ITO))>

As shown in FIG. 12, the light-extraction efficiency in terms of front brightness of organic EL element (1) was found to show almost no change up to the ratio (φ/a) of 1.0. However, once the ratio (φ/a) exceeded 1.0, the light-extraction efficiency increased drastically. The increasing rate was found to be higher than those of organic EL elements (2) to (4).

As shown in FIG. 13, the light-extraction efficiency in terms of integral intensity gradually increased from the ratio (φ/a) of 0. Once the ratio (φ/a) exceeded 1.0, the light-extraction efficiency increased drastically. The increasing rate was found to be higher than those of organic EL elements (2) to (4).

Thus, in the case of organic EL element (1), the ratio of A to B (A/B) was found to exceed 1 when the ratio (φ/a) for the light-extraction efficiency in terms of front brightness was 1.0 or greater. Here, A denotes a light-extraction efficiency in terms of front brightness when the lens was placed on the light extraction surface, and B denotes a light-extraction efficiency in terms of front brightness when the lens was not placed on the light extraction surface.

Also, the ratio (C/D) was found to exceed 1 when the ratio (φ/a) for the light-extraction efficiency in terms of integral intensity was 1.0 or greater. Here, C denotes a light-extraction efficiency in terms of integral intensity when the lens was placed on the light extraction surface, and D denotes a light-extraction efficiency in terms of integral intensity when the lens was not placed on the light extraction surface.

<Organic EL Element (2) (sm=1) (having a Microcavity Structure whose Optical Length is First Order)>

As shown in FIG. 12, the light-extraction efficiency in terms of front brightness of organic EL element (2) was found to gradually decrease up to the ratio (φ/a) of 1.0. Once the ratio (φ/a) exceeded 1.0, the light-extraction efficiency increased drastically. The increasing rate was found to be higher than those of organic EL elements (3) and (4).

As shown in FIG. 13, the light-extraction efficiency in terms of integral intensity decreased up to the ratio (φ/a) of 1.0. Once the ratio (φ/a) exceeded 1.0, the light-extraction efficiency increased. The increasing rate was found to be less than those of organic EL elements (3) and (4).

Thus, in the case of organic EL element (2), the ratio (A/B) exceeded 1 when the ratio (φ/a) was 1.2 or greater. Here, A denotes a light-extraction efficiency in terms of front brightness when the lens was placed on the light extraction surface, and B denotes a light-extraction efficiency in terms of front brightness when the lens was not placed on the light extraction surface.

Also, the ratio (C/D) exceeded 1 when the ratio (φ/a) was 1.6 or greater. Here, C denotes a light-extraction efficiency in terms of integral intensity when the lens was placed on the light extraction surface, and D denotes a light-extraction efficiency in terms of integral intensity when the lens is not placed on the light extraction surface.

<Organic EL Element (3) (sm=2) (having a Microcavity Structure whose Optical Length is Second Order)>

As shown in FIG. 12, the light-extraction efficiency in terms of front brightness of organic EL element (3) was found to decrease up to the ratio (φ/a) of 1.0. Once the ratio (φ/a) exceeded 1.0, the light-extraction efficiency increased. The increasing rate was less than that of organic EL element (2).

As shown in FIG. 13, the light-extraction efficiency in terms of integral intensity hardly changed up to the ratio (φ/a) of 1.0. Once the ratio (φ/a) exceeded 1.0, the light-extraction efficiency increased. The increasing rate was found to be higher than that of organic EL element (2) but less than that of organic EL element (4).

Thus, in the case of organic EL element (3), the ratio (A/B) exceeded 1 when the ratio (φ/a) was 1.4 or greater. Here, A denotes a light-extraction efficiency in terms of front brightness when the lens was placed on the light extraction surface, and B denotes a light-extraction efficiency in terms of front brightness when the lens is not placed on the light extraction surface.

Also, the ratio (C/D) exceeded 1 when the ratio (φ/a) was 1.1 or greater. Here, C denotes a light-extraction efficiency in terms of integral intensity when the lens was placed on the light extraction surface, and D denotes a light-extraction efficiency in terms of integral intensity when the lens was not placed on the light extraction surface.

<Organic EL Element (4) (sm=3) (having a Microcavity Structure whose Optical Length is Third Order)>

In the case of organic EL element (4), as shown in FIG. 12, the light-extraction efficiency in terms of front brightness was found to decrease up to the ratio (φ/a) of 1.0. However, once the ratio (φ/a) exceeded 1.0, the light-extraction efficiency increased. The increasing rate was less than those of organic EL elements (2) and (3).

As shown in FIG. 13, the light-extraction efficiency in terms of integral intensity gradually increased from the ratio (φ/a) of 0. Once the ratio (φ/a) exceeded 1.0, the light-extraction efficiency increased drastically. The increasing rate was found to be higher than those of organic EL elements (2) and (3).

Thus, in the case of organic EL element (4), the ratio (A/B) exceeded 1 when the ratio (φ/a) for the light-extraction efficiency in terms of front brightness was 1.5 or greater. Here, A denotes a light-extraction efficiency in terms of front brightness when the lens was placed on the light extraction surface, and B denotes a light-extraction efficiency in terms of front brightness when the lens was not placed on the light extraction surface.

Also, the ratio (C/D) exceeded 1 when the ratio (φ/a) for the light-extraction efficiency in terms of integral intensity was 1.0 or greater. Here, C denotes a light-extraction efficiency in terms of integral intensity when the lens was placed on the light extraction surface, and D denotes a light-extraction efficiency in terms of integral intensity when the lens was not placed on the light extraction surface.

### Example 2

Three types of top-emission type organic EL elements (5) to (7) were fabricated as follows.

<Fabrication of Organic EL Element (5) (sm=1) (having a Microcavity Structure whose Optical Length is First Order)>

Eagle 2000 (Corning Inc.) (thickness: 0.7 mm and refractive index: 1.5) was used as a glass substrate.

Next, aluminum (Al) was vacuum-deposited on the glass substrate so as to have a thickness of 100 nm, to thereby form an anode.

Next, on the Al film, 2-TNATA [4,4′,4″-tris(2-naphthylphenylamino)triphenylamine] and MnO₃ were vacuum-deposited at a ratio of 7:3 so as to have a thickness of 20 nm, to thereby form a hole injection layer.

Next, on the hole injection layer, 2-TNATA doped with F4-TCNQ (2,3,5,6-tetrafluoro-7,7,8,8-tetracyanoquinodimethane) at a concentration of 1.0% was vacuum-deposited so as to have a thickness of 11 nm, to thereby form a first hole transport layer.

Next, on the first hole transport layer, α-NPD [N,N′-(dinaphthylphenylamino)pyrene] was vacuum-deposited so as to have a thickness of 10 nm, to thereby form a second hole transport layer.

Next, on the second hole transport layer, electron hole transport material A having the following structural formula was vacuum-deposited so as to have a thickness of 3 nm, to thereby form a third hole transport material.

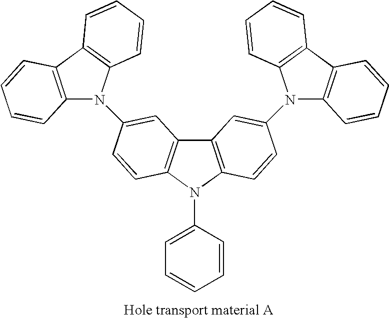

Next, on the third hole transport layer, CBP (4,4′-dicarbazole-biphenyl) serving as a host material and light-emitting material A serving as a light-emitting material were vacuum-deposited at a ratio of 85:15 so as to have a thickness of 20 nm, to thereby form a light-emitting layer.

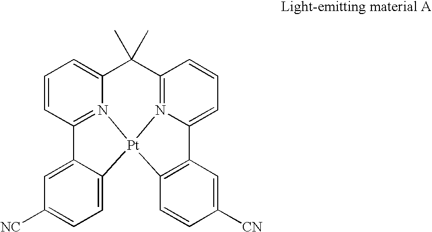

Next, on the light-emitting layer, BA1q (aluminum(III) bis(2-methyl-8-quinolinato)-4-phenylphenolate) was vacuum-deposited so as to have a thickness of 39 nm, to thereby form a first electron transport layer.

Next, on the first electron transport layer, BCP (2,9-dimethyl-4,7-diphenyl-1,10-phenanthorolin) was vacuum-deposited so as to have a thickness of 1 nm, to thereby form a second electron transport layer.

Next, on the second electron transport layer, LiF was vacuum-deposited so as to have a thickness of 1 nm, to thereby form an electron injection layer.

Next, on the electron injection layer, Ag was vacuum-deposited so as to have a thickness of 20 nm, to thereby form a cathode. When viewed from the light-emitting layer, the reflectance of the formed Ag film was 47% and the light transmittance thereof was 45%.

Through the above procedure, organic EL element (5) was fabricated.

The thus-obtained organic EL element (5) was found to have a first order microcavity structure whose optical length L(λ) is 1λ (where λ denotes a wavelength of emitted light).

<Fabrication of Organic EL Element (6) (sm=2) (having a Microcavity Structure whose Optical Length is Second Order)>

Organic EL element (6) was fabricated in the same manner as in the fabrication of organic EL element (5), except that the thickness of the first hole transport layer was changed from 11 nm to 141 nm.

The thus-obtained organic EL element (6) was found to have a second order microcavity structure whose optical length L(λ) is 2λ (where λ denotes a wavelength of emitted light).

<Fabrication of Organic EL Element (7) (sm=3) (having a Microcavity Structure whose Optical Length is Third Order)>

Organic EL element (7) was fabricated in the same manner as in the fabrication of organic EL element (5), except that the thickness of the first hole transport layer was changed from 11 nm to 271 nm.

The thus-obtained organic EL element (7) was found to have a third order microcavity structure whose optical length L(λ) is 3λ (where λ denotes a wavelength of emitted light).

The thus-obtained organic EL elements were optimized so as to emit green light (about 530 nm). In the organic EL elements, the value of a—the maximum length of a side of the light-emitting part (i.e., the light-emitting layer)—was 2 mm.

Next, the light distribution of each organic EL element was measured in the same manner as in Example 1. Through this evaluation, the angular distribution of light in glass can be obtained. The light distribution of organic EL element (5) is shown in FIG. 5, the light distribution of organic EL element (6) in FIG. 6, and the light distribution of the organic EL element (7) in FIG. 7.

As is clear from FIGS. 5 to 7, the light distribution (angular distribution of light) of each organic EL element in glass was found to depend greatly on the structure.

Organic EL element (5) (FIG. 5), organic EL element (6) (FIG. 6), and organic EL element (7) (FIG. 7) differ in the thickness of the hole transport layer and the optical length of the microcavity structure. As shown in FIGS. 5, 6 and 7, depending on whether the optical length of the microcavity structure was first, second or third order, the light distribution (angular distribution of light) was found to be varied.

Next, the light-extraction efficiency of each organic EL element was evaluated as follows.

### <Evaluation Experiments of Light-Extraction Efficiency>

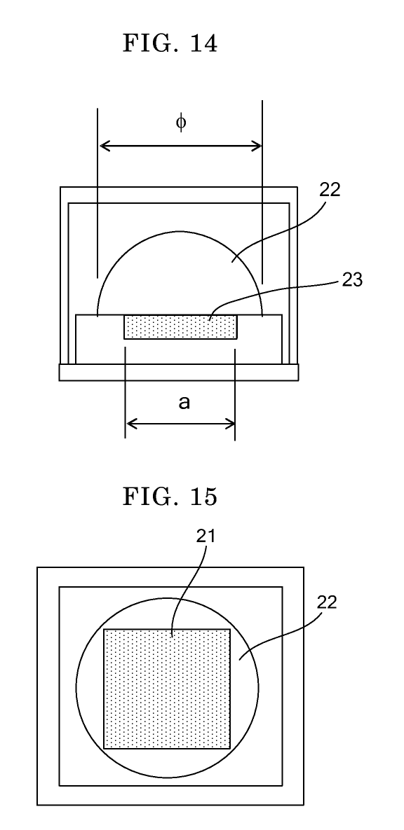

As shown in FIGS. 14 and 15, a semi-spherical lens 22 (which had been formed through cutting) (refractive index: 1.8) was attached to the light-extraction surface of an organic EL element with a resin containing dispersed inorganic particles (TiO₂) having high refractive index, to thereby fabricate organic EL devices. Then, φ (effective diameter of the lens) was changed from 0 mm to 8 mm.

In each organic EL device, the ratio (d/φ) was 0.1, where d denotes a distance between the light-emitting layer and the lens, and φ denotes an effective diameter of the lens.

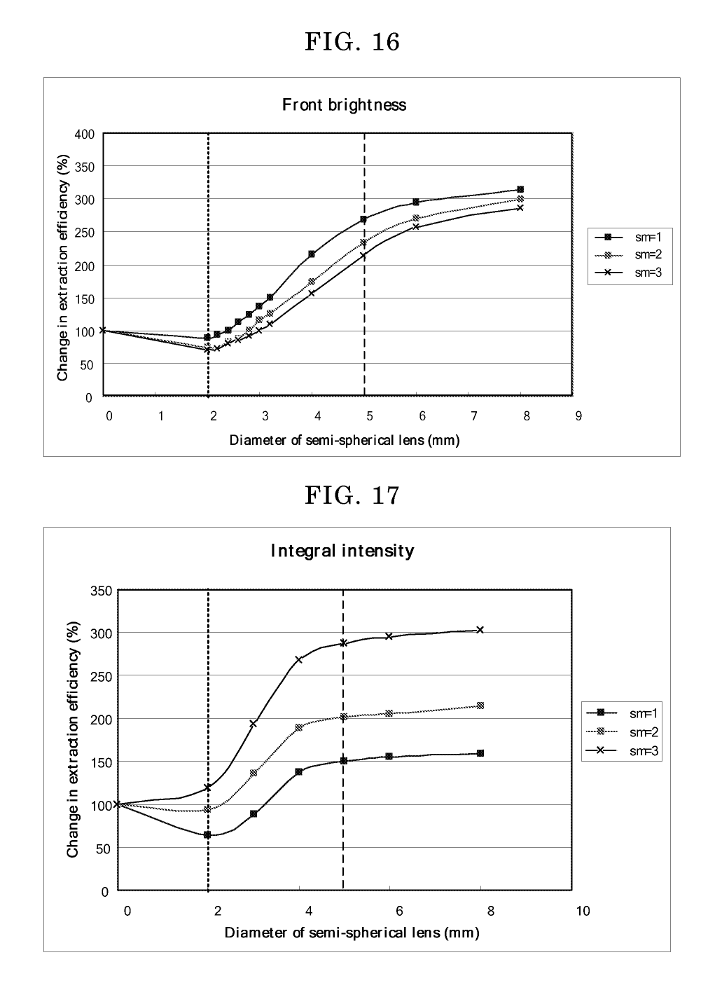

Similar to Example 1, the light-extraction efficiency of each organic EL device was measured. The light-extraction efficiencies in both integral intensity and front brightness were measured. The results are shown in FIG. 16 (front brightness) and FIG. 17 (integral intensity).

As is clear from FIGS. 16 and 17, the light-extraction efficiencies in both integral intensity and front brightness were found to increase with increasing φ (effective diameter of the lens) and the ratio (φ/a). The increasing rate was found to depend on the structure of the organic EL element. Next, description will be given to the above-described finding for each organic EL element.

<Organic EL Element (5) (sm=1) (having a Microcavity Structure whose Optical Length is First Order)>

As shown in FIG. 16, the light-extraction efficiency in terms of front brightness of organic EL element (5) gradually decreased up to the ratio (φ/a) of 1.0. Once the ratio (φ/a) exceeded 1.0, the light-extraction efficiency increased drastically. The increasing rate was found to be higher than those of organic EL elements (6) and (7).

Also, as shown in FIG. 17, the light-extraction efficiency in terms of integral intensity decreased up to the ratio (φ/a) of 1.0. Once the ratio (φ/a) exceeded 1.0, the light-extraction efficiency increased. The increasing rate was found to be less than those of organic EL elements (6) and (7).

Thus, in the case of organic EL element (5), the ratio (A/B) exceeded 1 when the ratio (φ/a) was 1.2 or greater. Here, A denotes a light-extraction efficiency in terms of front brightness when the lens was placed on the light-extraction surface, and B denotes a light-extraction efficiency in terms of front brightness when the lens was not placed on the light-extraction surface.

Also, the ratio (C/D) exceeded 1 when the ratio (φ/a) was 1.6 or greater. Here, C denotes a light-extraction efficiency in terms of integral intensity when the lens was placed on the light-extraction surface, and D denotes a light-extraction efficiency in terms of integral intensity when the lens was not placed on the light-extraction surface.

<Organic EL Element (6) (sm=2) (having a Microcavity Structure whose Optical Length is Second Order)>

As shown in FIG. 16, the light-extraction efficiency in terms of front brightness of organic EL element (6) decreased up to the ratio (φ/a) of 1.0. Once the ratio (φ/a) exceeded 1.0, the light-extraction efficiency increased. The increasing rate was found to be less than that of organic EL element (2).

As shown in FIG. 17, the light-extraction efficiency in terms of integral intensity thereof hardly changed up to the ratio (φ/a) of 1.0. Once the ratio (φ/a) exceeded 1.0, the light-extraction efficiency increased. The increasing rate was found to be higher than organic EL element (2) but less than that of organic EL element (4).

Thus, in the case of the organic EL element (6), the ratio (A/B) exceeded 1 when the ratio (φ/a) was 1.4 or greater. Here, A denotes a light-extraction efficiency in terms of front brightness when the lens was placed on the light-extraction surface, and B denotes a light-extraction efficiency in terms of front brightness when the lens was not placed on the light-extraction surface.

Also, the ratio (C/D) exceeded 1 when the ratio (φ/a) was 1.1 or greater. Here, C denotes a light-extraction efficiency in terms of integral intensity when the lens was placed on the light-extraction surface, and D denotes a light-extraction efficiency when the lens was not placed on the light-extraction surface.

<Organic EL Element (7) (sm=3) (having a Microcavity Structure whose Optical Length is Third Order)>

As shown in FIG. 16, the light-extraction efficiency in terms of front brightness of organic EL element (7) decreased up to the ratio (φ/a) of 1.0. Once the ratio (φ/a) exceeded 1.0, the light-extraction efficiency increased. The increasing rate was found to be less than those of organic EL elements (2) and (3).

As shown in FIG. 17, the light-extraction efficiency in terms of integral intensity gradually increased from the ratio (φ/a) of 0. Once the ratio (φ/a) exceeded 1.0, the light-extraction efficiency increased drastically. The increasing rate was found to be higher than those of organic EL elements (2) and (3).

Thus, in the case of organic EL element (7), the ratio (A/B) exceeded 1 when the ratio (φ/a) was 1.5 or greater. Here, A denotes a light-extraction efficiency in terms of front brightness when the lens was placed on the light-extraction surface, and B denotes a light-extraction efficiency in terms of front brightness when the lens was not placed on the light-extraction surface.

Also, the ratio (C/D) exceeded 1 when the ratio (φ/a) was 1.0 or greater.

Here, C denotes a light-extraction efficiency in terms of integral intensity when the lens was placed on the light-extraction surface, and D denotes a light-extraction efficiency when the lens was not placed on the light-extraction surface.

As is clear from FIGS. 12 and 16 regarding the light-extraction efficiency, the improving effect on the light-extraction efficiency by virtue of an increase in the effective diameter of a lens was found to be almost the maximum level, when the ratio (φ/a) was 2.5 or greater.

If φ (the effective diameter of the lens) was much larger than a (the maximum length of a side of the light-emitting layer), the numerical aperture would decrease when such an organic EL element was used as a display. The numerical aperture of a well-known conventional organic EL display is about 5%, at which the ratio (φ/a) is 4.47 when lenses are placed on a glass substrate in square grid. Thus, the upper limit of the ratio (φ/a) is 4.47.

From the results obtained in Examples 1 and 2 described above, the optimum effective diameter of a lens varied with the structure of an organic EL element. Thus, it was found that, without considering an optimum combination of a lens and the structure of an organic EL element, the light-extracting effect could not be obtained sufficiently in some regions.

Although the above-described results are obtained from Examples 1 and 2 performed on one pixel of green (about 530 nm), similar results were obtained for pixels of blue (about 470 nm) and red (about 630 nm).

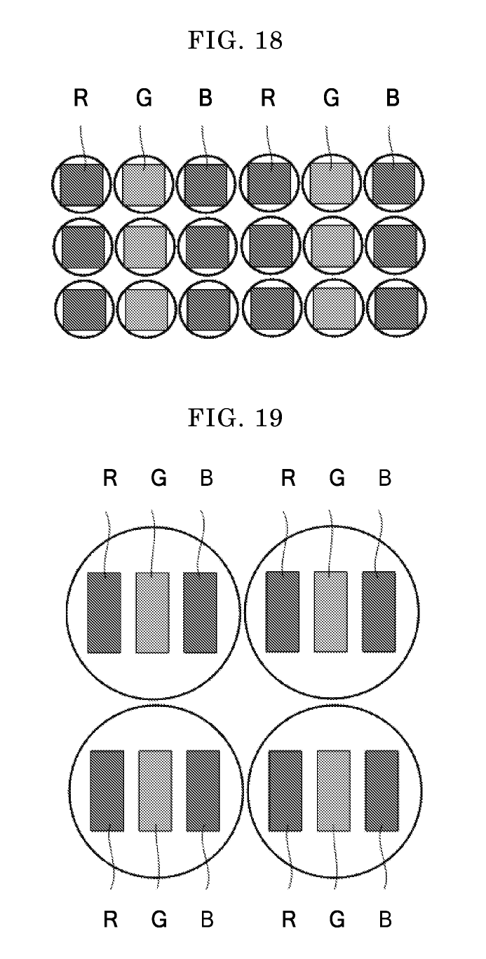

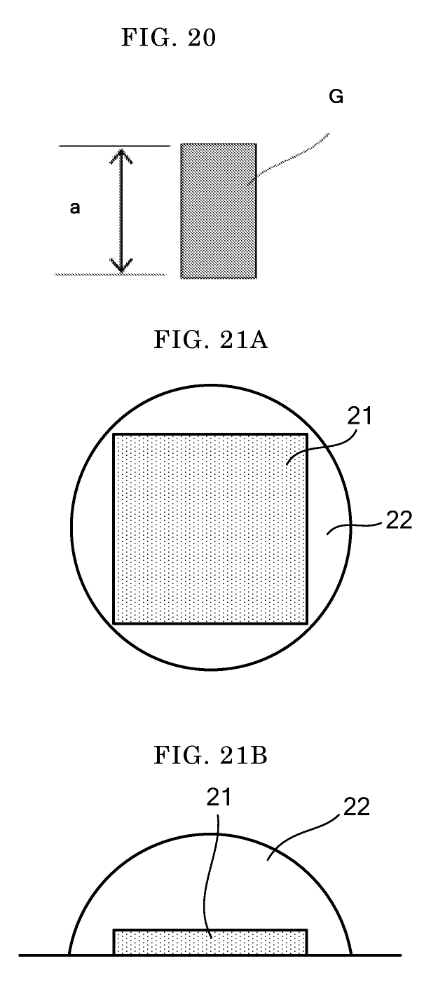

Upon fabricating a device containing RGB three pixels (i.e., red (R), green (G) and blue (B)), the RGB three pixels may be individually covered with lenses as shown in FIG. 18, or may be covered as one unit with a lens as shown in FIG. 19. Notably, as shown in FIG. 20, when each pixel is not a square but a rectangle with sides of different lengths, the length of a longer side is used as a (the maximum length of a side of a light-emitting part (i.e., a light-emitting layer)).

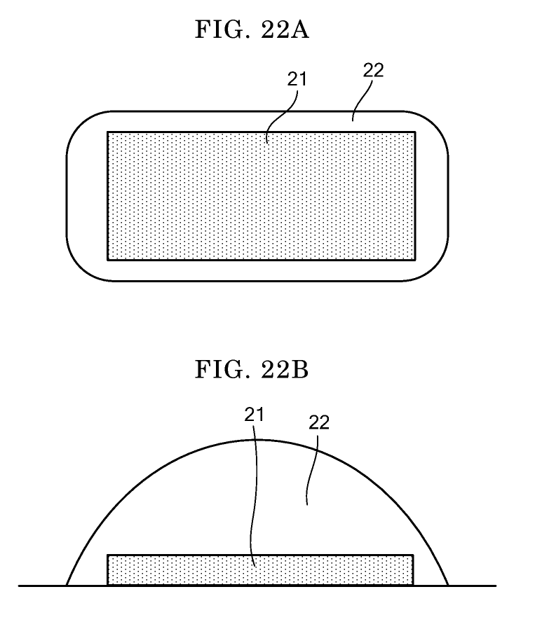

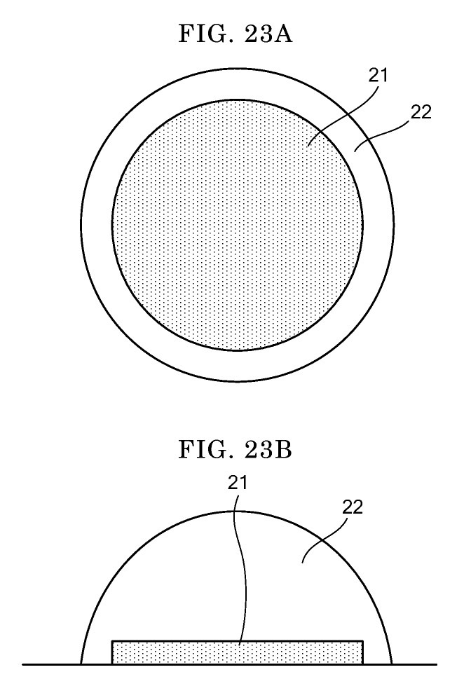

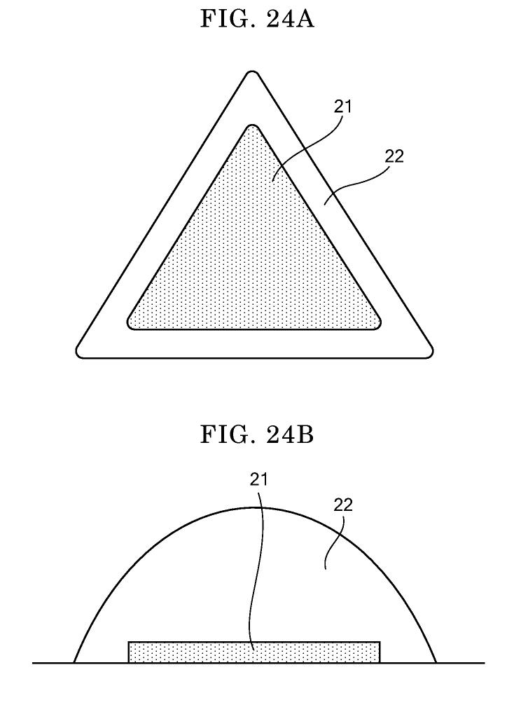

The shape of the pixel is not particularly limited and may be changed according to the intended purpose. For example, a lens 22 may be placed over a square pixel 21 (as shown in FIGS. 21A and 21B), a lens 22 may be placed over a rectangular pixel 21 (as shown in FIGS. 22A and 22B), a lens 22 may be placed over a circular pixel 21 (as shown in FIGS. 23A and 23B) and a lens 22 may be placed over a triangular pixel 21 (as shown in FIGS. 24A and 24B).

Also, organic EL elements having a value of a (the maximum length of a side of the light-emitting part (i.e., the light-emitting layer)) of 2 mm were fabricated and evaluated in Examples 1 and 2. Even if value a is not 2 mm, optical characteristics remain unchanged so long as the ratio (φ/a) is maintained.

Actually, an organic EL element having a value of a (the maximum length of a side of the light-emitting part (i.e., the light-emitting layer)) of 2 μm was fabricated and evaluated in the same manner as described above. Here, a glass substrate with a thickness (d) of 20 μm was used for the experiment. As a result, the optical characteristics thereof were found to be equivalent to those of the organic EL element having value a of 2 mm (the maximum length of a side of the light-emitting part (i.e., the light-emitting layer)).

The organic EL device of the present invention has high light-extraction efficiency and reduced image bleeding, and thus, are suitably used in organic EL display devices of both a bottom-emission type and a top-emission type. Specifically, the organic EL device of the present invention may be suitably used in various fields, such as computers, displays for automobiles, outdoor displays, domestic and commercial devices, domestic appliances, transportation-related displays, clock displays, calendar displays, luminescent screens and audio devices.

What is claimed is:

1. An organic electroluminescence device comprising:
an organic electroluminescence display part which includes an anode, a cathode and at least a light-emitting layer disposed therebetween, and
a lens which controls an optical path of light emitted from the light-emitting layer,
wherein the organic electroluminescence device has a ratio of A to B (A/B) of greater than 1, where A denotes a light-extraction efficiency in terms of front brightness when the lens is placed on a surface from which the light is extracted and B denotes a light-extraction efficiency in terms of front brightness when the lens is not placed on the surface from which the light is extracted, and
wherein the organic electroluminescence device has a ratio of φ to a (φ/a) of 1.0 or greater, where a denotes the maximum length of a side of the light-emitting layer and φ denotes an effective diameter of the lens.

2. The organic electroluminescence device according to claim 1, wherein the organic electroluminescence display part has a first order microcavity structure whose optical length L(λ) is 1λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.2 or greater, where a denotes the maximum length of a side of the light-emitting layer and φ denotes an effective diameter of the lens.

3. The organic electroluminescence device according to claim 1, wherein the organic electroluminescence display part has a second order microcavity structure whose optical length L(λ) is 2λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.4 or greater, where a denotes the maximum length of a side of the light-emitting layer and φ denotes an effective diameter of the lens.

4. The organic electroluminescence device according to claim 1, wherein the organic electroluminescence display part has a third order microcavity structure whose optical length L(λ) is 3λ, where λ denotes a wavelength of light emitted, wherein the organic electroluminescence device has a ratio of A to B (A/B) of greater than 1, where A denotes a light-extraction efficiency in terms of front brightness when the lens is placed on the surface from which the light is extracted and B denotes a light-extraction efficiency in terms of front brightness when the lens is not placed the surface from which the light is extracted, and wherein the organic electroluminescence device has a ratio of φ to a (φ/a) of 1.5 or greater, where a denotes the maximum length of a side of the light-emitting layer and φ denotes an effective diameter of the lens.

5. The organic electroluminescence device according to claim 1, wherein the anode of the organic electroluminescence display part is a transparent electrode which has a reflectance of 10% or less when viewed from the light-emitting layer, wherein the organic electroluminescence device has a ratio of A to B (A/B) of greater than 1, where A denotes a light-extraction efficiency in terms of front brightness when the lens is placed on a surface from which the light is extracted and B denotes a light-extraction efficiency in terms of front brightness when the lens is not placed on the surface from which the light is extracted, and wherein the organic electroluminescence device has a ratio of φ to a (φ/a) of 1.0 or greater, where a denotes the maximum length of a side of the light-emitting layer and φ denotes an effective diameter of the lens.

6. The organic electroluminescence device according to claim 1, wherein the ratio (φ/a) is 2.5 or greater.

7. The organic electroluminescence device according to claim 1, wherein the ratio (φ/a) is 4.47 or less.

8. The organic electroluminescence device according to claim 1, wherein the organic electroluminescence device has a ratio of d to φ (d/φ) of 0.1 or less, where d denotes a distance between the light-emitting layer and the lens and φ denotes an effective diameter of the lens.

9. A design method of an organic electroluminescence device which includes an organic electroluminescence display part, containing an anode, a cathode and at least a light-emitting layer disposed therebetween, and a lens which controls an optical path of light emitted from the light-emitting layer, the design method comprising:
designing the organic electroluminescence device so as to have a ratio of A to B (A/B) of greater than 1, where A denotes a light-extraction efficiency in terms of front brightness when the lens is placed on a surface from which the light is extracted, and B denotes a light-extraction efficiency in terms of front brightness when the lens is not placed on the surface from which the light is extracted, and to have a ratio of φ to a (φ/a) of 1.0 or greater, where a denotes the maximum length of a side of the light-emitting layer and φ denotes an effective diameter of the lens.
